(19) United States
(12) Patent Application Publication
(10) Pub. No.: US 2010/0200067 A1
(43) Pub. Date: Aug. 12, 2010

(54) SUBSTRATE FOR SEMICONDUCTOR DEVICE AND METHOD FOR ITS MANUFACTURE

(75) Inventors: Shengzhong Liu, Rochester Hills, MI (US); Yanhua Zhou, Rochester Hills, MI (US); Chaolan Hu, Rochester Hills, MI (US); Arindam Banerjee, Bloomfield Hills, MI (US); Jeffrey Yang, Troy, MI (US); Subhendu Guha, Bloomfield Hills, MI (US)

Correspondence Address: GIFFORD, KRASS, SPRINKLE,ANDERSON & CITKOWSKI, P.C, PO BOX 7021, TROY, MI, 48007-7021, US

(73) Assignee: United Solar Ovonic LLC, Auburn Hills, MI (US)

(21) Appl. No.: 12/369,016

(22) Filed: Feb. 11, 2009

(51) Int. Cl. H01L 31/0224; C25D 1/06

(52) U.S. Cl. 136/265; 136/252; 205/116

(57) ABSTRACT

A metal and oxygen material such as a transparent electrically conductive oxide material is electro deposited onto a substrate in a solution deposition process. Process parameters are controlled so as to result in the deposition of a high quality layer of material which is suitable for use in a back reflector structure of a high efficiency photovoltaic device. The deposition may be carried out in conjunction with a masking member which operates to restrict the deposition of the metal and oxygen material to specific portions of the substrate. In particular instances the deposition may be implemented in a continuous, roll-to-roll process. Further disclosed are semiconductor devices and components of semiconductor devices made by the present process, as well as apparatus for carrying out the process.

### STATEMENT OF GOVERNMENT INTEREST

This invention was made, at least in part, under U.S. Government, Department of Energy, Contract No. DE-FC36-07G017053. The Government may have rights in this invention.

### FIELD OF THE INVENTION

This invention relates generally to the electro deposition of transparent, electrically conductive oxide materials and in particular to the deposition of transparent, electrically conductive metal oxide materials.

### BACKGROUND OF THE INVENTION

A number of electronic devices incorporate one or more layers of transparent, electrically conductive material. Such devices include, but are not limited to, semiconductor devices such as electronic memory, photovoltaic devices, photo sensors, other photo responsive devices, display devices and the like. These layers are typically fabricated from transparent, electrically conductive metal oxide (TCO) materials; and, zinc oxide based materials comprise one particular TCO material. Transparent, electrically conductive zinc oxide materials are often not stoichiometrically pure, but typically incorporate species such as suboxides, hydroxides, ionic species, dopants and the like which can function to enhance electrical conductivity of the electronic device. Therefore, within the context of this disclosure, it is to be understood that “metal and oxygen materials” are meant to include materials based thereon and may also include suboxides, hydroxides, and other species. For example, materials based on zinc and oxygen (sometimes referred to as “zinc oxide” or “zinc oxide material”) may also include suboxides of zinc, hydroxides of zinc such as Zn(OH)₂, Zn²⁺ ions (typically in the form of zinc salts) and other such species. Likewise other metal and oxygen materials, such as tin and indium based material, may include oxides, suboxides, hydroxides and ionic species. It is also to be understood that in the context of this disclosure, the metal and oxygen materials may also include dopants or modifiers such as boron, which can function to tailor the electrical conductivity of the deposited oxide material (e.g. ZnO) layer and/or control the physical morphology of the deposited layer.

Zinc oxide materials are one metal and oxygen material which has significant utility as components of the back reflector structure of high efficiency photovoltaic devices and the present invention will be explained with reference to such materials; however, it is to be understood that the principles of this invention are applicable to the deposition of other metal and oxygen materials. The back reflector is an important component of such devices. It is disposed at the back surface of the photovoltaic device, typically as a portion of the support substrate, and functions to reflect and redirect unabsorbed photons which have passed through the overlying, photovoltaically active semiconductor layers back through those layers for reabsorption. A typical back reflector structure includes a highly reflective metal layer such as a layer of silver or aluminum having a microtextured layer of transparent, electrically conductive zinc oxide material disposed thereatop. The textured nature of the zinc oxide material serves to scatter the reflected photons of incident light that were not absorbed on the initial pass through the superposed solar cell material thereby allowing for their subsequent absorption in their secondary pass through said solar cell.

In order to maximize the efficiency of the photovoltaic device, the electronic, optical and physical properties of the zinc oxide material must be carefully controlled. The zinc oxide material must have good electrical conductivity, since photo current generated by the overlying semiconductor layers must pass through the zinc oxide material for collection in the subjacent substrate electrode. Hence, the electrical resistivity of the oxide material represents a parasitic loss in the photovoltaic device. Likewise, the material must have good optical transparency, since reflected photons may pass through the layer numerous times (depending upon the absorption characteristics of the semiconductor material of the photovoltaic device and the scattering characteristics of the zinc oxide and back reflector layers), and any optical absorption will also represent a loss in device efficiency. Finally, the microtexture of the layer needs to be controlled so as to optimize the scattering of the reflected photons so as to maximize the opportunity of those photons to be absorbed by the overlying semiconductor layers. Therefore, the controllable deposition of high quality zinc oxide materials is important to the preparation of high efficiency photovoltaic devices.

The prior art has generally utilized vacuum deposition processes, such as sputtering, for the deposition of zinc oxide materials. However, such processes are inherently equipment intensive and relatively slow deposition rates coupled with high capital expenditure costs and high operational expenses adversely impact the cost of producing photovoltaic devices. In addition, such deposition processes are inherently slow and represent a bottleneck in the photovoltaic device deposition process. Therefore, if high volume deposition processes are to be attempted, the back reflector fabrication stations must be extremely large and expensive.

Because of the problems associated with the vacuum deposition of such materials, the prior art has attempted to deposit zinc oxide materials by high speed, low cost electro deposition processes wherein zinc oxide materials are electroplated onto substrates in an aqueous bath. Some such processes are disclosed, for example, in U.S. Pat. Nos. 6,133,061; 6,224,736; 6,238,808; and 6,379,521. Despite various attempts, the prior art has not, heretofore, been able to reliably and repeatedly electro deposit zinc oxide materials having electrical, optical and physical properties which maximize their utility in back reflector structures of high efficiency photovoltaic devices. Furthermore, prior art processes have encountered problems of compatibility when such materials were deposited on particular substrates.

As will be explained in detail hereinbelow, the present invention provides a method and apparatus whereby high quality zinc oxide and other transparent conductive oxide materials may be electro deposited onto a variety of substrates of the type utilized in high efficiency photovoltaic devices. Furthermore, the present invention provides a method and apparatus whereby the deposition of the zinc oxide and other transparent conductive oxide materials may be limited to preselected portions of the substrate. Finally, the present invention provides a method and apparatus which is compatible with the high speed, roll-to-roll fabrication of large area, high efficiency, photovoltaic devices. These and other advantages of the present invention will be apparent from the drawings, description, and discussion which follow.

### BRIEF DESCRIPTION OF THE INVENTION

The present invention is directed to a method for electro depositing a layer of a metal and oxygen material, such as a zinc and oxygen material, onto a substrate. In a first aspect of the present invention, the metal and oxygen material is electroplated onto a substrate in a process wherein a first portion of the thickness of the layer is deposited on the substrate at a first deposition rate, and thereafter a second portion of the thickness of the layer is deposited atop the first portion of the thickness at a second deposition rate which differs from the first deposition rate. In a specific instance, the second deposition rate is slower than the first deposition rate.

In another aspect of the present invention, a metal oxygen material is electro deposited onto a substrate in a process wherein at least a portion of the substrate is covered with a masking member which prevents the deposition of the metal and oxygen material onto those portions of the substrate to which it is affixed. The masking member may, in some instances, be magnetically affixable to the substrate. In specific instances, the electro deposition process is carried out on an elongated web of substrate material which is continuously advanced through a deposition system which includes a deposition station wherein the metal and oxygen material is deposited on the substrate. In this embodiment of the invention, a belt-like body of masking material is brought into contact with a back surface of the substrate member while it is in the deposition station and while the metal and oxygen material is being deposited onto the front surface of the web of substrate material. In some specific instances, the deposition system may include a biasing member such as a platen or series of rollers which urge the belt of masking material into contact with the substrate.

In yet another aspect of the present invention, the substrate member is maintained in a partiphobic orientation while the metal and oxygen material is being deposited thereonto so as to at least partially inhibit the incorporation of particulate material into the depositing layer of metal and oxygen material.

In another aspect of the present invention, a layer of metal and oxygen material is electroplated onto a substrate which is disposed in an electrolyte in a spaced apart relationship with an electrode. In this process, a power supply is operative, when energized, to establish a flow of electrical current through the electrode, the electrolyte and the substrate so as to deposit a layer of metal and oxygen material on the substrate. In this process, at least two of the following steps are implemented: inputting ultrasonic energy into the electrolyte during at least a portion of the time while the layer of metal and oxygen material is being deposited onto the substrate; periodically interrupting the flow of electrical current between the electrode, the electrolyte and the substrate while the layer of metal and oxygen material is being deposited; maintaining the substrate in a partiphobic orientation while the layer of metal and oxygen material is being deposited thereupon; bubbling a gas through the electrolyte; and energizing the power supply at a first level while a first portion of the metal and oxygen material is being deposited on the substrate so that the first portion is deposited at a first deposition rate, and thereafter energizing the power supply at a second level during the time that a second portion of the layer is being deposited atop the first portion so that the second portion is deposited at a second deposition rate. In a specific instance, the second deposition rate is less than the first deposition rate. In some particular instances, at least three of the foregoing steps are implemented. In further embodiments of this aspect of the invention, at least one more step from the following group is implemented: monitoring the composition of the electrolyte bath; monitoring the level of a dopant in the deposited metal and oxygen material; utilizing a dimensionally stable electrode; utilizing an electrode configured as a hollow basket having particles of the metal contained therein and utilizing a filter shielded electrode.

The present invention may be implemented in a continuous process, and in specific instances may be utilized to fabricate back reflector structures for high efficiency photovoltaic devices.

The present invention also includes substrates having metal and oxygen materials deposited thereupon in accord with the foregoing. The substrates of the present invention may be used as back reflector structures for photovoltaic devices. In specific instances, the present invention is directed to substrates which include a layer of a highly reflective metal such as aluminum or silver disposed thereupon and having a highly adherent metal and oxygen layer, such as a zinc and oxygen layer, electro deposited thereupon wherein these substrates are characterized in that they do not include any vacuum deposited seed layer of a metal and oxygen material thereupon so that all of the metal and oxygen material deposited upon the reflective metal is deposited from a solution in an electro deposition process in accord with the present invention.

The present invention is also directed to apparatus for carrying out the aforedescribed methods and for manufacturing the aforedescribed articles.

### BRIEF DESCRIPTION OF THE DRAWINGS

FIG. 1 is a cross-sectional view of a photovoltaic device showing a back reflector structure which includes a zinc oxide material deposited in accord with the present invention;

FIG. 2 is a cross-sectional view of a schematic electroplating apparatus which may be utilized to carry out the method of the present invention;

FIG. 3 is a flowchart depicting one embodiment of the present invention;

FIG. 4 is a schematic depiction of an apparatus for implementing the method of the present invention in a continuous process;

FIG. 5 is an enlarged view of a portion of a deposition station of the apparatus of FIG. 4 better illustrating the masking system; and

FIG. 6 is a depiction of a deposition station generally similar to that of FIG. 5 but including a biasing platen.

### DETAILED DESCRIPTION OF THE INVENTION

The present invention will be described with reference to the deposition of metal oxides such as zinc oxide materials in connection with the fabrication of back reflector structures for high efficiency photovoltaic devices. However, it is to be understood that the principles of the present invention may be readily extended to any application wherein high quality metal oxide materials are electro deposited in a high speed, high volume process. As noted above, such applications may include the fabrication of display devices, sensor devices, light emitting devices, and the like.

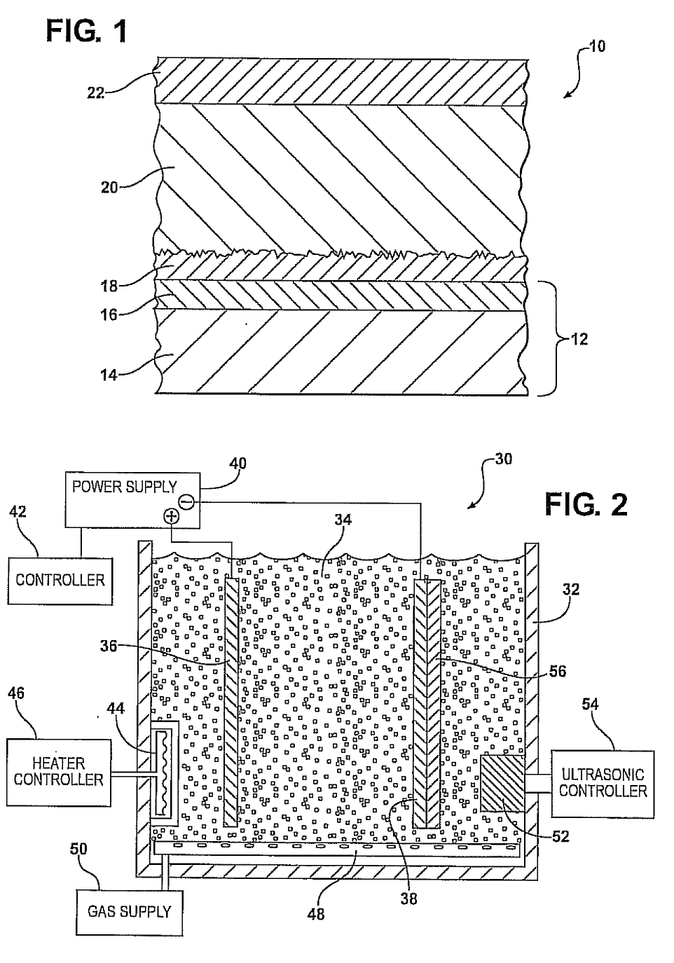

Referring now to FIG. 1, there is shown a cross-sectional view of a generalized high efficiency photovoltaic device 10. The device incorporates a substrate 12 which functions to support the remainder of the device and operates to provide a bottom, current collecting, electrode for the device. In the illustration, the substrate 12 is comprised of two separate layers. The first layer 14 is a body of stainless steel. Disposed thereatop is a relatively thin layer of a highly reflective metal 16, such as aluminum or silver. In other embodiments of photovoltaic device, the substrate may be comprised of a body of electrically insulating material such as a polymer, glass, ceramic or the like, provided that a layer of electrically conductive material is disposed thereupon.

Disposed atop the substrate 12 is a layer of transparent, electrically conductive metal oxide material, in an exemplary embodiment a zinc oxide material, 18. As noted above, this layer is primarily comprised of ZnO, but may further include other zinc based species as well as dopants and the like. The material comprising the zinc oxide layer 18 is at least partially crystalline and as such the surface of this layer may have a texture corresponding to the crystalline features of the material. In general, it is preferable that the crystalline features have a size range of approximately 200-1000 nanometers so as to maximize the scattering of visible light therefrom. The layer 18 has good electrical conductivity and good optical transparency.

Disposed atop the zinc oxide layer 18 is a body of photovoltaic semiconductor material 20. The active semiconductor layers of this body 20 operate to absorb incident photons and create carrier pairs which are collected by the electrodes of the device. As is known in the art, this body 20 may be comprised of a number of layers of semiconductor materials disposed in various configurations. In one particular embodiment, the semiconductor body 20 is comprised of hydrogenated silicon alloy materials, and as such may comprise one or more stacked triads, each triad comprised of a layer of substantially intrinsic semiconductor material interposed between p-doped and n-doped semiconductor layers.

Disposed atop the photovoltaic body 20 is a top electrode layer 22, which in the instance of this particular configuration of device, is fabricated from an optically transparent, electrically conductive material such as ZnO or another TCO material. As is known in the art, current collecting structures such as bus bars, grids and the like may be disposed upon the top electrode 22.

In the operation of the photovoltaic device, photons pass into the device through the top electrode layer 22 and are absorbed by the photovoltaic body 20 wherein they generate electron-hole pairs. The inherent, built-in electric field of the photovoltaic body 20 separates the photogenerated holes and electrons of these carrier pairs and they are collected by the respective top electrode 22 and substrate 12. Photons which are not absorbed by the photovoltaic body 20 pass through the zinc oxide layer 18 and are reflected by the reflective layer 16. The textured nature of the zinc oxide layer 18 scatters the reflected photons so that their angulated path back through the photovoltaic body 20 is increased as compared to non-scattered photons. And in some embodiments, the reflective layer 16 will also include a textured configuration to also aid in scattering the reflected photons.

Referring now to FIG. 2, there is shown a generalized system 30 as may be employed for the deposition of zinc oxide materials in accord with the present invention. The system 30 includes a tank 32 which is configured and operable to retain a volume of electrolyte material 34 therein. The apparatus further includes an electrode station having a deposition electrode 36 supported therein. As shown in FIG. 2, the electrode 36 is configured as a plate, comprised primarily of a metallic material such as zinc metal. It is to be understood that the apparatus of FIG. 2 is generalized, and in some instances the electrode may be configured as a mesh, and/or as a nonplanar body. In one embodiment, the electrode is a hollow, basket-like, perforated body comprised of a material which is inert to the deposition process, such as Ti, Pt, Pd, Au, or the like. Zinc particles in tie form of shot or the like are disposed in the hollow body. In another embodiment, a filter is positioned about the electrode to shield the electrode and prevent particulate matter from reaching the surface of the substrate upon which the deposition is taking place. In one embodiment the filter is in the form of a porous, polyethylene filter bag, disposed so as to surround the electrode. In another embodiment, the electrode is an inert, dimensionally stable electrode fabricated from an inert material such as titanium. As is known in the art, in electroplating processes of this type, all of the metal ions which form the deposited metal and oxygen layers are provided from the electrolyte. As is further to be understood, the electrode station may also include fixturing members such as clamps, brackets and the like for supporting the electrode body. Also, as will be further discussed hereinbelow, in some instances the electrode station may include a plurality of discrete electrodes.

The system of FIG. 2 supports a substrate 38 in the body of electrolyte material 34. As described above, the substrate 38 may comprise a single layered structure or a multilayered structure.

The electrode 36 and the substrate 38 are both in electrical communication with a power supply station which includes power supply 40 which in turn is controlled by a controller 42. The power supply 40 is a DC power supply, and the electrode 36 is in communication with the positive terminal of the power supply 40 and the substrate is in electrical communication with the negative terminal of the power supply 40. The illustrated embodiment of FIG. 2 includes a single power supply 40; however, it is to be understood that in oiler embodiments, the power supply station may include a number of power supplies operative to energize a plurality of discrete electrodes and/or to provide different levels of power.

As is further illustrated, the system 30 includes a heater 44 disposed in the tank 32. The heater 44 is operative to maintain the electrolyte 34 at a preselected temperature, and in that regard, the heater 44 has a controller 46 associated therewith. As illustrated herein, the heater 44 is an electrical resistance heater; although, other types of heater as is known in the art may be likewise utilized.

The system 30 also preferably includes a gas bubbler 48 disposed in the tank. The bubbler 48 has a gas supply 50 associated therewith and is operable, when activated, to bubble a gas, such as air or nitrogen, through the electrolyte 34, so as to keep the electrolyte stirred.

The system further includes an ultrasonic transducer 52 disposed in the tank. The transducer is energized by a controller 54 and is operative, when energized, to introduce ultrasonic energy into the electrolyte material 34. While not wishing to be bound by speculation, the inventors hereof presume that the ultrasonic energy may act to maintain the cleanliness of the surface of the deposition substrate and/or the cleanliness of the depositing layer by removing unwanted species therefrom.

The systems of the present invention may further include a monitoring station for measuring the composition of the electrolyte during the deposition process, so as to determine the concentration of metal ions, dopants and other species. Such monitoring is preferably done in situ and in real time, and assures the uniformity and consistency of the deposited materials. Monitoring may be by techniques including potentiometric techniques, chemical techniques such as EDTA titration, spectroscopic techniques and the like. Monitoring can be utilized in combination with reagent supply systems operating in a feedback mode. Thus, for example, if the metal concentration of the electrolyte is too low, additional metal can be added. Or, if the pH is too high, acid can be automatically added. Likewise, the system can control and adjust dopant reagent levels based upon measured levels in the electrolyte and/or the deposited layer.

In FIG. 2, the substrate material 38 is shown as having a body of masking material 56 affixed to one surface thereof. The masking material operates to shield portions of the substrate so that in the process, zinc oxide material is unable to be deposited onto those shielded portions of the substrate. This feature is optional in the practice of the present invention; however, in a number of processes and device configurations it has been found beneficial to so restrict the deposit of the zinc oxide material. The masking material may be variously configured and adhered to the substrate and as such may comprise a polymeric resist coating. However, in one specific embodiment of the present invention, the masking material 56 comprises a sheet of material which is magnetically affixable to at least a portion of one surface of the substrate. In this regard, the masking material 56 may comprise a sheet of magnetized metal, or it may comprise a body of polymeric material having magnetized particles dispersed therein. In specific instances, the masking material is electrically insulating, so as to preclude deposition thereonto.

In a typical process for the deposition of zinc oxide material in accord with the present invention, the electrolyte material 34 comprises an approximately 0.03 molar solution of Zn(NO₃)₂. In some embodiments, the electrolyte will also include relatively small amounts of adhesion promoting material such as ethylenediaminetetraacetic acid (EDTA). Other chelating materials and/or adhesion promoters such as fumaric acid, malic acid, various other compounds having multiple functional groups, as well as compounds such as sucrose may likewise be included. Typically, the concentration of these materials is in the range of 1-200 ppm. The electrolyte material may also include one or more dopant or modifying species which operate to enhance the electrical conductivity of the deposited zinc oxide material. One specific doping species utilized in the present invention comprises boron, and it may be present in the electrolyte in the form of boric acid at a concentration in the range of 0.1%-1.0% by weight. The electrolyte is generally maintained at a temperature in the range of 50-100° C. during the deposition process, and in a typical instance, the electrolyte is maintained at a temperature of approximately 80° C.

In those instances where tin and oxygen based materials are being deposited, the electrolyte will include one or more tin salts such as tin chloride, tin acetate, tin sulfate, and the like. The deposition of indium based materials will employ an electrolyte which includes indium salts such as indium chloride, indium nitrate, indium sulfate and the like.

The power supply is activated so as to establish an electrical potential of approximately 0.5 to 20 volts between the electrode 36 and the substrate 38. This potential will cause the deposition of zinc oxide material onto the substrate, and the rate of deposition will be proportional to the power density at the substrate. Therefore, the control of deposition power will allow for the control of the deposition rate. In a typical deposition, power density at the substrate will be in the range of 0.5-20 mA/cm².

In order to enhance the uniformity of the deposited zinc oxide, the electrolyte bath 34 is at least periodically stirred, and this may be done by use of a recirculation pump (not shown) and/or by bubbling a gas through the electrolyte from the bubbler 48. It has been found, in this process, that air or nitrogen may be employed for this purpose; however, other gases which are inert or do not otherwise degrade the deposition process may likewise be employed.

In accord with another aspect of the present invention, it has been found that the quality of the deposited zinc oxide material is improved if ultrasonic energy is at least periodically introduced into the electrolyte bath. In one embodiment, the ultrasonic transducer 52 is energized at a power level of approximately 500 watts, for example. The configuration of the ultrasonic energy system employed will depend on the configuration of the electrical device and other aspects of the electro deposition system.

In another aspect of the present invention, it has been found advantageous to operate the power supply 40 in a pulsed mode wherein the DC current applied to the electrode 36 and substrate 38 is periodically interrupted. In a typical process, the current is pulsed at a rate of 1 to 10 Hz. While not wishing to be bound by speculation, Applicant presumes that operation in the pulsed mode allows for equilibration of deposition conditions at the surface of the substrate and thereby promotes the deposition of materials having optimum compositions and morphology.

In accord with yet a further aspect of the present invention, the inventors hereof have found that very high quality deposits of zinc oxide material may be prepared in a multi-deposition rate process. In this embodiment of the present invention, the substrate is initially coated with a first layer of zinc oxide material in a relatively high rate deposition process. High rate deposition may be achieved by controlling the power supply so as to energize the electrode 36 and substrate 38 with a relatively high level of power. This produces a relatively fast deposition of a relatively thick portion of the body of zinc oxide material. Thereafter, the power supply energizes the electrode 36 and substrate 38 at a lower level of power so as to deposit zinc oxide material upon the previously deposited layer, at a lower rate. It is believed that this lower rate material manifests a very good crystalline structure which optimizes the performance of the zinc oxide layer. Use of the dual rate process thus achieves the benefits of high average deposition rate while producing a body of zinc oxide material having superior electrical, optical and physical properties. In further refinements of this process, the body may be deposited at three or more deposition rates. Also, it is to be noted that the change in deposition rate need not be abrupt, and within the context of this aspect of the invention, the deposition rate may be varied on a continuous basis, by varying current density, so that the material transitions from high rate to low rate, or from a low rate to a high rate, in a non-stepwise, or only partially stepwise manner.

In yet another aspect of the present invention, it has been found that superior quality materials are prepared when the substrate 38 is maintained in an orientation which will allow gravity to inhibit the accumulation of particulate matter thereupon. As such, the substrate 38 may be oriented vertically as is shown in FIG. 2. However, other orientations which will inhibit particle accumulations may be employed. For example, the substrate may be disposed in a horizontal orientation with the deposition surface facing downward. In other instances, the substrate may be disposed in an angled relationship with a vertical axis, provided that the deposition surface is downwardly inclined so as to inhibit particulate accumulation. Within the context of this disclosure, all of such orientations of the substrate, wherein gravity acts (at least in part) to inhibit particle accumulation on the deposition surface, are referred to as “partiphobic”.

The zinc oxygen materials produced by the present invention have very good physical, optical and electronic properties which make them ideally suited for use in back reflector structures of photovoltaic devices. It is believed that this combination of properties is resultant from the independent and/or synergistic effect of at least two and perhaps more of the aforedescribed features of the present invention, namely the use of pulsed power, deposition of the material in an at least dual layered structure at differing power levels, ultrasonic cleaning of the depositing layer during the deposition process, and use of a partiphobic substrate orientation which precludes particulate inclusions. Other factors which can contribute to the quality of the materials produced by the present process include the use of in situ monitoring of electrolyte bath composition; in situ monitoring of dopant composition and profiles; and the use of electrode structures such as the hollow basket, dimensionally stable electrode and/or filter shielded electrode previously discussed. Typical layer thicknesses in back reflector structures are on the order of 0.1 to 3 microns, and the high speed nature of the deposition process of the present invention greatly enhances the economics and physical implementation of the fabrication process as compared to methods wherein the layer is entirely deposited by vacuum processes.

While the present invention provides for the high speed electrochemical deposition of zinc oxide materials, it is to be understood that in some instances, the invention may be implemented in connection with an overall fabrication process wherein some portions of the zinc oxide material may be deposited in a vacuum process such as sputtering. For example, commonly employed substrates for photovoltaic devices comprise stainless steel having a reflective coating of silver or aluminum deposited thereupon. The reflective layer is fairly thin and is often deposited by sputtering or some other vacuum process. In some instances, it has been found advantageous to vacuum deposit a relatively thin “seed” layer of zinc oxide material atop the reflective layer. This deposition is typically carried out by sputtering, and the total layer thickness is on the order of 5-100 nanometers; consequently, deposition time is relatively fast. It has been found that in some instances, the use of the vacuum deposited seed layer facilitates the deposition and adhesion of the electrochemically deposited zinc oxide material. It should be noted that the use of a seed layer is optional, and in accord with the present invention, the inventors herein have been able to electro deposit a high quality TCO material having very good adhesion properties and device operational parameters atop various reflective substrates without a seed layer, thereby reducing manufacturing costs considerably. Elimination of the seed layer is particularly important in those instances where the reflective layer is deposited by electroplating, since this allows for a total atmospheric pressure process. It has been found that the inclusion of adhesion promoters such as EDTA in the electrolyte enhances the adhesion of the electro deposited layer to the reflective metal, and thereby eliminates the need for a seed layer. In an experimental series it was found that the adhesion of zinc oxide layers directly electro deposited onto silver layers from an EDTA containing bath was at least as good as that of comparable layers of zinc oxide electro deposited onto a silver layer having a vacuum coated seed layer of zinc oxide thereupon. If the adhesion promoter is eliminated from the bath, adhesion of the zinc oxide layer is poor in the absence of the seed layer. In this experimental series, adhesion was measured by the tape lift-off method.

In one specific implementation of the present invention, the substrate is approximately 5 mils tick layer of stainless steel. In those instances where a reflective layer is to be sputtered thereatop, an approximately 100 nanometer thick adhesion layer of titanium is vacuum deposited upon the stainless steel. Subsequently, a reflective layer of silver or aluminum, having a thickness in the range of 100-500 nanometers is deposited upon the substrate. Thereafter, a seed layer of zinc oxygen material having a thickness of approximately 40 nanometers is deposited atop the reflective layer. The thus prepared substrate is coated with a layer of zinc oxide material in the process of the present invention. The thickness of this layer is generally in the range of 0.1-3 microns depending upon specific applications.

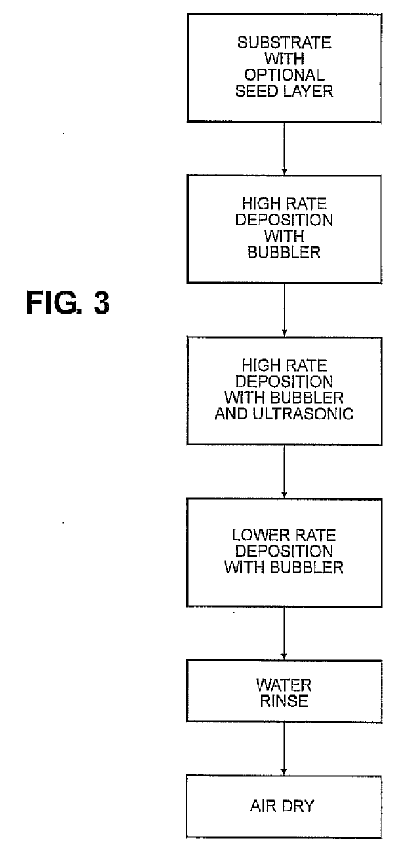

Referring now to FIG. 3, there is shown a generalized flowchart depicting one embodiment of the present invention. As is shown in FIG. 3, the process employs a substrate which, as mentioned above, may optionally include a seed layer thereupon. In a first portion of tie deposition process, the zinc oxide material is deposited onto the substrate at a relatively high deposition rate, which in some instances is approximately 10 nm/sec. This initial deposition is carried out at a temperature in the range of 50-100° C., and typically at a temperature of 80° C. The electrolyte in the deposition tank is agitated by activating the gas bubbler system; however, agitation may optionally be carried out by pumps, stirrers or the like. After a portion of the layer (typically 30-80; and in specific instances 50-70% of its thickness) has been deposited, ultrasonic energy is input to the deposition tank. Deposition conditions are maintained at a high rate, and agitation of the bath is also continued. The ultrasonic energy serves to remove undesirable solution particulates from the depositing layer. Any pitting left by the removal of the loosely adherent materials is filled in by the depositing zinc oxide material. In this second stage of the process, the remainder of the thickness of the final zinc oxide layer is deposited.

In the third stage of the deposition process, a further portion of the layer of zinc oxide material is deposited at a relatively low deposition rate. In particular instances, this rate is in the range of approximately 1-5 nm/sec. The deposition bath is maintained at approximately the same temperature it was in the first two stages, and agitation of the electrolyte is maintained through the use of the bubbler or other means.

Other modes of deposition may be employed. In one instance, the initial deposition may be at a low rate, followed by high rate deposition; and optionally followed by a second low rate deposition. In general, it is believed that low rate deposition promotes the formation of a layer having larger crystals which operate to promote optimum light scattering. Also, the low rate material can provide good adhesion to subjacent layers. In addition, low rate material can provide a template for subsequently deposited high rate material so that the crystalline structure of the high rate material resembles that of the low rate material to some degree.

Once the total thickness of the layer of zinc oxide material is deposited, the substrate is then rinsed with water and dried. Drying is typically carried out utilizing atmospheric air either in an oven or through the use of a blower. Drying is generally carried out at elevated temperatures, typically in the range of 25-200° C. for times of approximately 2 minutes. The drying step serves to remove water, but also allows for the at least partial conversion of zinc hydroxide species into zinc oxide species. The drying also can function to anneal the material, thereby further increasing its adherence to the substrate. In one particular instance, the drying/annealing is at 120° C. for two minutes; in another, it is at 150° C. for 1 minute. Following the drying/annealing, the process is complete, and the substrate may be subsequently processed into photovoltaic devices.

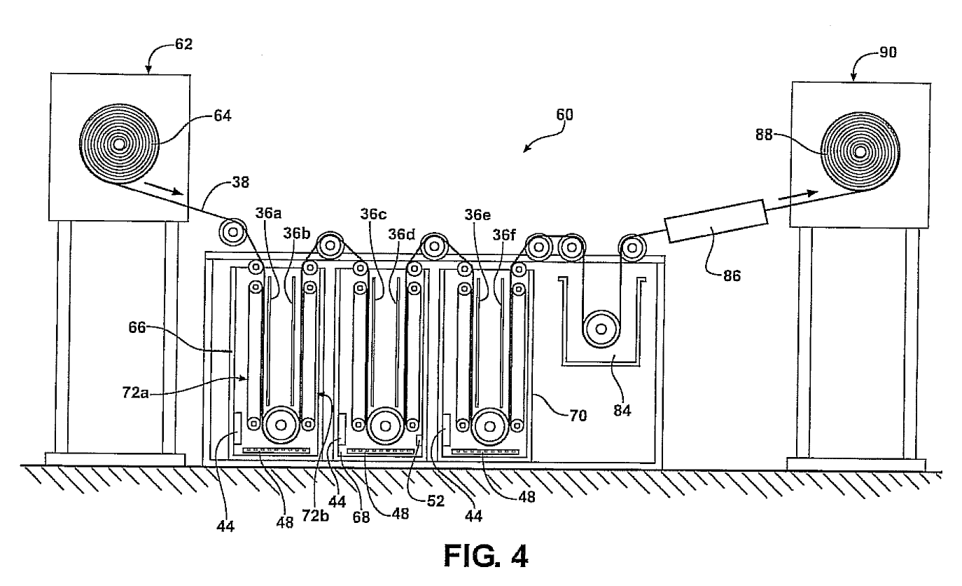

The process of the present invention may be readily implemented in a continuous, roll-to-roll process for the preparation of photovoltaic substrate material, and one such implementation is shown in FIG. 4. Depicted therein is a roll-to-roll deposition apparatus 60 for the coating of an elongated substrate web with a zinc/oxygen material. The system 60 of FIG. 4 includes a payoff station 62 which supports and feeds out a web of substrate material 38 from a supply roll 64. As is known in the art, the payoff station may include turning rollers, steering rollers, a tensioning mechanism and the like.

The system 60 includes three deposition stations 66, 68 and 70, although it is to be understood that in other implementations, greater or lesser numbers of deposition stations may be employed. In this particular implementation, the stations 66, 68 and 70 are configured to carry out the three stages of the deposition as described with reference to FIG. 3. As such, the first station 66 carries out a relatively high speed deposition wherein the electrolyte material is agitated by the bubbler 48. In the second station 68, high speed deposition is carried out utilizing bubbler agitation as well as ultrasonic energy input from the ultrasonic transducer 52. The third deposition station 70 is used for the low rate deposition. It also includes a bubbler 48 for maintaining agitation of the electrolyte.

Each of the stations includes a heater 44, and it is notable that in this embodiment, each deposition station 66, 68 and 70 includes two deposition electrodes. In this regard, the first station includes electrodes 36a, 36b, the second station includes electrodes 36c, 36d and the third includes electrodes 36e, 36f. Use of dual electrodes speeds up the deposition process. As described with reference to FIG. 2, the electrodes 36 are all in communication with an appropriate power supply and energized at power levels sufficient to provide a desired deposition rate.

As discussed above, it is frequently desirable to include a body of masking material which operates to prevent deposition of the zinc/oxygen material onto particular portions of the substrate. In the illustrated embodiment, each deposition station includes a masking system which as illustrated is comprised of two portions 72a, 72b.

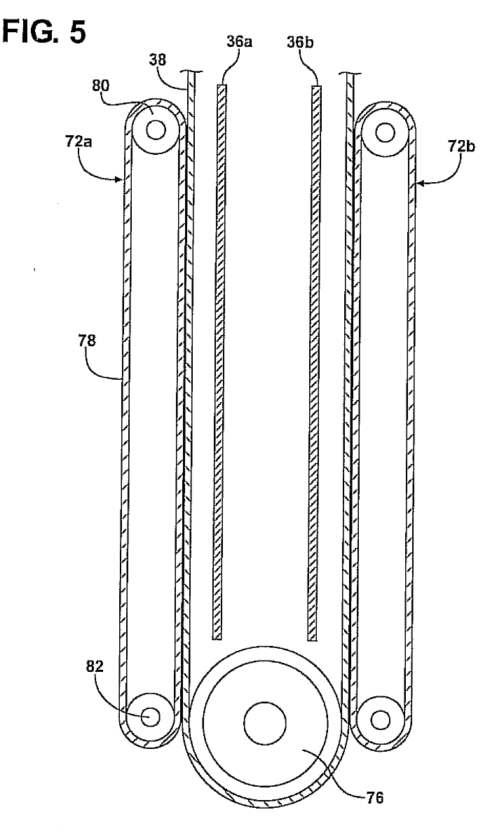

Referring now to FIG. 5, there is shown an enlarged view of a portion of the first deposition station of FIG. 4, better illustrating the masking system. As depicted, a portion of the substrate web 38 is advanced past a first deposition electrode 36a, about a turning roller 76, and past a second deposition electrode 36b. The first masking system 72a is disposed so as to contact the back surface of the substrate 38 with a body of masking material 78, when it is in the region of the first electrode 36a. The masking material 78 is flexible, electrically insulating and magnetic, and as such may comprise a polymer having a magnetic substance embedded therein. The masking material 78 is configured as a continuous web, and it is supported by a first 80 and a second 82 roller. In the operation of the system, the web 38 advances through the deposition station and is contacted by the magnetic material 78 which adheres thereto. The web of magnetic material 78 travels along with the substrate, past the electrode 36a. The magnetic nature of the masking material maintains it in contact with the substrate. After the substrate 38 leaves the region of the first electrode, the second roller 82 pulls the masking material 78 away from the substrate 38. The second masking system 72b is disposed in association with the second electrode 36b and operates in a similar manner to the first masking system 72a.

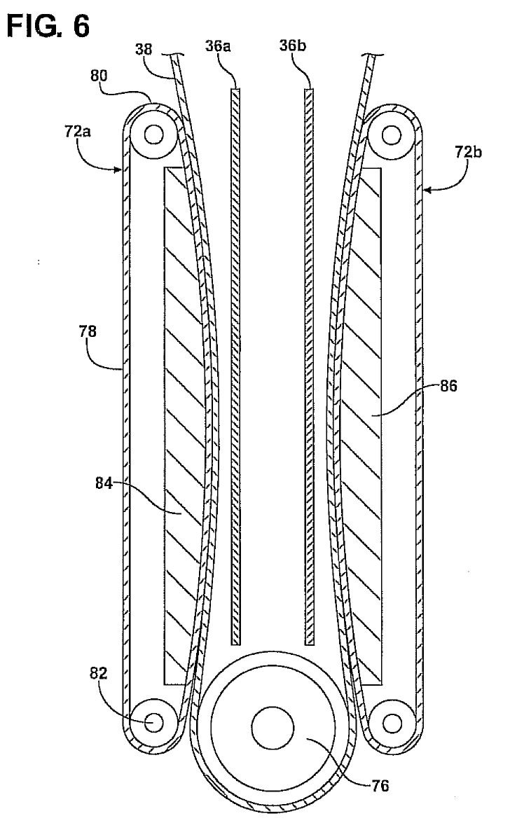

The substrate masking system may be configured to include rollers, platens, and the like which can assist in biasing the masking member against the substrate. These biasing systems may be used in combination with a magnetically affixable masking member; although, in some instances, the biasing force may be sufficient to assure good contact between the substrate and the biasing member so that magnetic attraction need not be employed. Referring now to FIG. 6, there is shown one embodiment of biasing system as configured to be utilized in a deposition station of the type generally shown in FIG. 5; and in that regard, similar elements will be identified by similar reference numerals. The deposition station of FIG. 6 includes a first and a second deposition electrode 36a, 36b disposed and operative to electro deposit a layer of zinc oxide material onto a web of substrate material 38 passing through the deposition station. The deposition station of FIG. 6 further includes a first masking system 72a and a second masking system 72b which, as previously described, include a flexible, electrically insulating body of masking material 78 supported by a first 80 and a second 82 roller. The system of FIG. 6 further includes a curved biasing platen 84 which is disposed so as to contact the belt of masking material 78 and urge that material against a portion of the substrate 38. A second such platen 86 is associated with the second masking system 72b. Biasing may be accomplished by otherwise configured members. For example, the biasing platens 84, 86 may be replaced by one or more rollers. Since the biasing platens urge the masking material into contact with the substrate, the masking material need not be magnetic, although a magnetic body may be utilized.

Returning now to FIG. 4, it will be seen that the system 60 further includes a rinsing station 84 disposed downstream of the deposition stations 66, 68 and 70. The rinsing station 84 comprises a tank configured so that the coated substrate passes therethrough wherein it is rinsed with water. The rinsing station 84 may further include agitators, stirrers or the like for enhancing the rinse action. It may also include a flow-through system for continuously replacing the rinse water. In some instances, the rinse station may comprise two or more discrete rinse tanks.

Downstream of rinsing station 84 is a drying station 86 wherein the coated web is dried as described above. The drying station may comprise an oven, a drying tunnel, or the like and may include radiant heaters, hot air blowers or the like. Following the drying, the substrate material is then wound onto a take-up reel 88 in a take-up station 90.

J The coating of the zinc and oxygen material may also be implemented into a single, continuous process in which a reflective layer is electroplated onto a stainless steel web and thereafter coated with the zinc and oxygen material. In this regard the apparatus may include a first deposition station wherein the substrate is electroplated with a reflective layer of silver or aluminum. For example, silver may be electroplated onto the stainless steel from an electrolyte bath comprising: 37.5 g/l dimethylhydantoin, 12.0 g/l silver nitrate, 0.38 g/l thiamine hydrochloride, 7.5 g/l potassium chloride and 7 g/l potassium hydroxide. Plating takes place at a temperature of 60-90° C., using a silver electrode at a current density of about 3 mA/cm² and deposits a highly reflective silver layer at a rate of about 2 nm/sec. Aluminum may likewise be electroplated by processes known in the art.

The system of FIG. 4 produces an elongated web of substrate material which may subsequently be employed in a continuous process for the fabrication of photovoltaic devices. In that regard, the roll of material may be transferred to a photovoltaic deposition apparatus. In yet other instances, the substrate coating system may be placed in line with, or incorporated into, a photovoltaic deposition apparatus. For example, a roll to roll process may be implemented in which a reflective layer of silver or aluminum is first electroplated onto the substrate, and thereafter a layer of a zinc and oxygen material is electroplated onto the substrate in the same apparatus. The coated substrate may then be conveyed to a series of semiconductor deposition chambers associated with the same apparatus, or it may be subsequently conveyed to separately disposed semiconductor deposition chambers.

The present invention provides a method and apparatus for the rapid, efficient deposition of high quality layers of metal oxide material, such as zinc oxide material. The invention has been described with regard to particular apparatus and particular operating conditions as specifically adapted for the preparation of substrates for high efficiency photovoltaic devices. However, it is to be understood that the principles of the present invention may be extended to other methods and apparatus and to processes for the preparation of devices and materials other than those for use in photovoltaic applications. As such, numerous modifications and variations of the invention will be apparent to those of skill in the art in view of the teaching presented herein. It is to be understood that the foregoing drawings, discussion and description are illustrative of specific embodiments of the invention, but are not meant to be limitations upon the practice thereof. It is the following claims, including all equivalents, which define the scope of the invention.

1. A light reflective electrode for use in a semiconductor device, said electrode comprising:
a substrate member;
a layer of a light reflective metal disposed upon said substrate; and
a layer of a solution deposited transparent electrically conductive metal and oxygen material disposed directly atop said layer of light reflective metal without any intervening body of a vacuum deposited material therebetween.

2. The electrode of claim 1, wherein said light reflective metal comprises a metal selected from the group consisting of silver, aluminum: and combinations thereof.

3. The electrode of claim 1, wherein said layer of light reflective metal is an electroplated layer of metal.

4. The electrode of claim 1, wherein said substrate comprises stainless steel.

5. The electrode of claim 1, wherein said metal and oxygen material comprises a zinc and oxygen material.

6. The electrode of claim 5, wherein said zinc and oxygen material comprises a member selected from the group consisting of: ZnO, clusters of ZnO, Zn²⁺ ions, Zn(OH)₂, and combinations thereof.

7. The electrode of claim 5, wherein said zinc and oxygen material has a crystalline structure.

8. The electrode of claim 7, wherein said zinc and oxygen material has crystalline features having a size in the range of 200-1000 nm.

9. The electrode of claim 1, wherein the thickness of the layer of said metal and oxygen material is in the range of 0.1-3 microns.

10. The electrode of claim 1, wherein the thickness of the layer of light reflective metal is in the range of 100-500 nm.

11. A photovoltaic device which includes the electrode of claim 1.

12. A method for manufacturing a light reflective electrode, said method comprising the steps of:
providing a substrate member;
depositing a layer of a light reflective metal onto said substrate; and
electro depositing, in a solution deposition process, a layer of a transparent, electrically conductive, metal and oxygen material directly upon the layer of light reflective metal, in the absence of any intervening body of vacuum deposited material.

13. The method of claim 12, wherein the step of depositing said layer of light reflective metal on said substrate comprises electro depositing said layer of metal in a solution deposition process.

14. The method of claim 13, wherein the step of electro depositing said layer of metal and said layer of transparent, electrically conductive metal and oxygen material are both carried out in a single deposition apparatus.

15. The method of claim 12, wherein said body of substrate material comprises an elongated web of substrate material and wherein said step of electro depositing said layer of transparent, electrically conductive metal and oxygen material is carried out in a continuous process in a deposition station wherein said web of substrate material is continuously advanced through said deposition station.

16. The method of claim 12, wherein said step of electro depositing said layer of transparent, electrically conductive metal and oxygen material comprises electro depositing a layer of a zinc and oxygen material.

17. The method of claim 12, wherein said step of depositing said layer of light reflective metal comprises depositing a layer of a metal selected from the group consisting of silver, aluminum, and combinations thereof.

18. The method of claim 12, wherein the substrate comprises stainless steel.
